(19) United States
(12) Patent Application Publication
(10) Pub. No.: US 2024/0233842 A1
(43) Pub. Date: Jul. 11, 2024

(54) MANAGING TRAP-UP IN A MEMORY SYSTEM

(71) Applicant: Micron Technology, Inc., Boise, ID (US)

(72) Inventors: Pitamber Shukla, Boise, ID (US); Chi Ming W. Chu, Boise, ID (US); Avinash Rajagiri, Boise, ID (US); Ching-Huang Lu, Fremont, CA (US); Kenneth W. Marr, Boise, ID (US)

(21) Appl. No.: 18/393,354

(22) Filed: Dec. 21, 2023

Related U.S. Application Data
(60) Provisional application No. 63/437,535, filed on Jan. 6, 2023.

(51) Int. Cl. G11C 16/34; G11C 16/08; G11C 16/28

(52) U.S. Cl. CPC G11C 16/3495; G11C 16/08; G11C 16/28; G11C 16/3404

(57) ABSTRACT

Methods, systems, and devices for managing trap-up in a memory system are described. A request to erase a block of a memory device may be received. Based on the request, a scan operation for determining whether a threshold voltage distribution for a dummy word line associated with the block satisfies one or more criteria may be performed. Based on the scan operation, whether to perform one or more program and erase cycles on the block using a first voltage level for a de-biasing operation of a program and erase (P/E) cycle may be determined. The first voltage level may be lower than a second voltage level for one or more prior de-biasing operations of one or more prior P/E cycles performed on the block. The block of memory may be managed based on whether the P/E cycling with the debiasing operation having the voltage level is performed.

### CROSS REFERENCE

The present application for patent claims priority to U.S. Patent Application No. 63/437,535 by Shukla et al., entitled “MANAGING TRAP-UP IN A MEMORY SYSTEM,” filed Jan. 6, 2023, which is assigned to the assignee hereof, and which is expressly incorporated by reference herein.

### FIELD OF TECHNOLOGY

The following relates to one or more systems for memory, including managing trap-up in a memory system.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports managing trap-up in a memory system in accordance with examples as disclosed herein.

FIG. 2 illustrates an example of a memory device that supports managing trap-up in a memory system in accordance with examples as disclosed herein.

FIG. 3 illustrates an example of a memory architecture 300 that supports managing trap-up in a memory system in accordance with examples as disclosed herein.

FIG. 4 illustrates an example of a set of operations for managing trap-up in a memory system in accordance with examples as disclosed herein.

FIG. 5 illustrates an example of a set of operations for managing trap-up in a memory system in accordance with examples as disclosed herein.

FIG. 6 illustrates an example of a diagram for managing trap-up in a memory system in accordance with examples as disclosed herein.

FIG. 7 illustrates a block diagram of a memory system that supports managing trap-up in accordance with examples as disclosed herein.

FIG. 8 illustrates a flowchart showing a method or methods that support managing trap-up in a memory system in accordance with examples as disclosed herein.

### DETAILED DESCRIPTION

A memory system may scan a memory device for transistors used to select a string of memory cells (which may be referred to as “select transistors”) that have experienced threshold voltage failures—e.g., threshold voltages that have increased beyond a threshold amount. Based on the results of the scan, the memory system may retire blocks (e.g., mark the blocks as no longer available for storage operations) that have a line for accessing one or more select transistors (which may be referred to as a “select line”) that have experienced threshold voltage failures—e.g., a select line that is associated with a threshold voltage distribution for the select transistors that satisfies one or more criteria.

Retiring blocks as soon as a high-VT scanning operation identifies a respective select line as satisfying a high-VT condition may result in the unnecessary retiring of blocks, increase an overhead associated with managing retired blocks, increase memory system yield loss, and the like. Thus, configurations and techniques for avoiding the retiring blocks associated with high-VT select lines, for attempting to recover retired blocks associated with high-VT select lines, or both, may be desired.

To reduce a rate of retiring blocks and, in some examples, to enable recovery of blocks, the high-VT scanning operation may be modified to identify high-VT dummy word lines and apply (one or more times) a lowered de-bias voltage across the high-VT dummy word lines. Based on applying the lowered de-bias voltage, a determination may be made as to whether threshold voltage characteristics of the high-VT dummy word lines can be improved. If the threshold voltage characteristics of the dummy word lines can be sufficiently improved, a corresponding block may be maintained in (or, if previously retired, returned to) the pool of operational blocks (which may also be referred to as the pool of “usable blocks”). Alternatively, if the threshold voltage characteristics of the dummy word lines cannot be sufficiently improved, a corresponding block may be marked to indicate that it has limited operating life (that is, a limited quantity of remaining program and erase cycles) and, in some examples, removed from the pool of operational blocks (e.g., if the corresponding block has reached a threshold quantity of program and erase cycles).

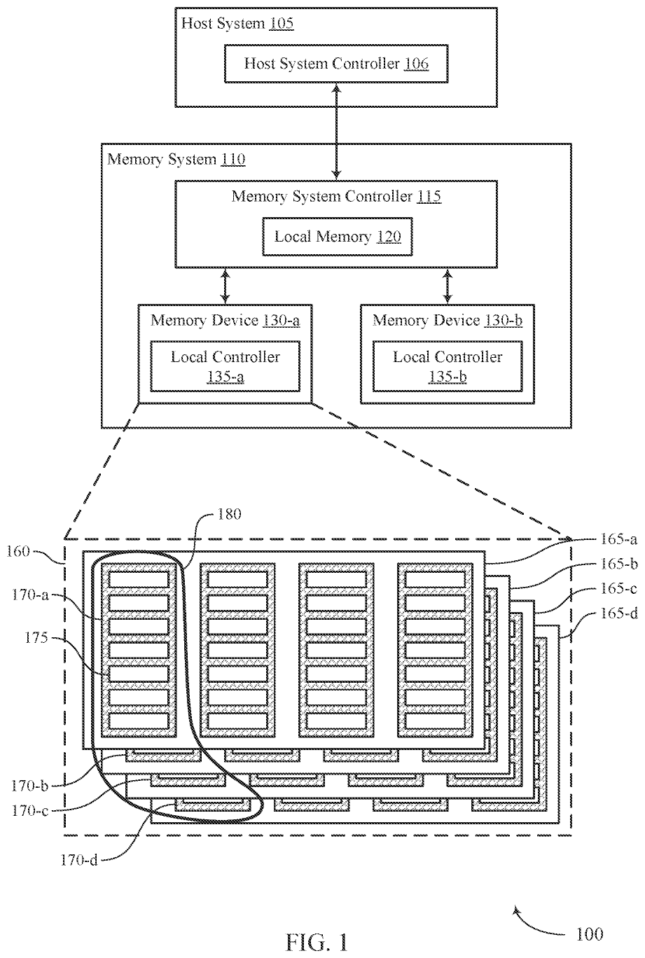

FIG. 1 illustrates an example of a system 100 that supports managing trap-up in a memory system in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory. ROM, phase change memory (PCM), self-selecting memory, other chalcogenide-based memories, ferroelectric random access memory (RAM) (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

The system 100 may include any quantity of non-transitory computer readable media that support managing trap-up in a memory system. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

A controller (e.g., the memory system controller 115) may receive a request to erase a block of a memory device. Based on the request, the controller may perform a scan operation for determining whether a threshold voltage distribution for a dummy word line associated with the block satisfies one or more criteria. Based on the scan operation, the controller may determine whether to perform one or more program and erase cycles on the block using a first voltage level for a de-biasing operation of the P/E cycle. The first voltage level may be lower than a second voltage level for one or more prior de-biasing operations of one or more prior P/E cycles performed on the block. The controller may perform an operation for managing the block of memory based on whether the P/E cycling with the debiasing operation having the voltage level is performed.

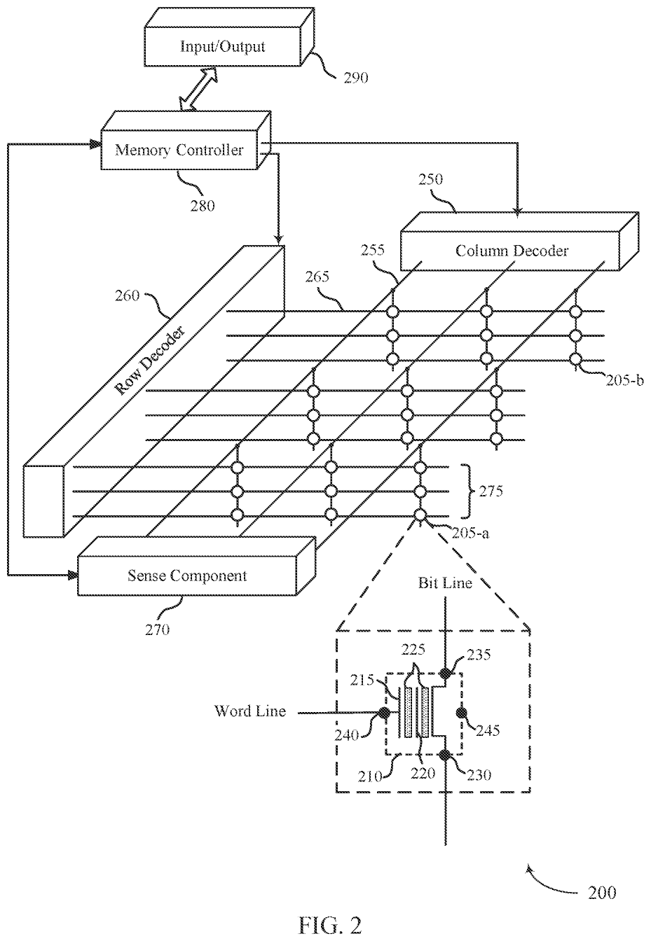

FIG. 2 illustrates an example of a memory device 200 that supports managing trap-up in a memory system in accordance with examples as disclosed herein. FIG. 2 is an illustrative representation of various components and features of the memory device 200. As such, the components and features of the memory device 200 are shown to illustrate functional interrelationships, and not necessarily physical positions within the memory device 200. Further, although some elements included in FIG. 2 are labeled with a numeric indicator, some other corresponding elements are not labeled, even though they are the same or would be understood to be similar, in an effort to increase visibility and clarity of the depicted features. The memory device 200 may be an example of a memory device 130 as described with reference to FIG. 1.

The memory device 200 may include one or more memory cells 205, such as memory cell 205-a and memory cell 205-b. In some examples, a memory cell 205 may be a NAND memory cell, such as in the blow-up diagram of memory cell 205-a. Each memory cell 205 may be programmed to store a logic value representing one or more bits of information. In some examples, a single memory cell 205—such as a memory cell 205 configured as a single-level cell (SLC)—may be programmed to one of two supported states and thus may store one bit of information at a time (e.g., a logic 0 or a logic 1). In some other examples, a single memory cell 205—such a memory cell 205 configured as a multi-level cell (MLC), a tri-level cell (TLC), a quad-level cell (QLC), or other type of multiple-level memory cell 205—may be programmed to one state of more than two supported states and thus may store more than one bit of information at a time. In some cases, a multiple-level memory cell 205 (e.g., an MLC memory cell, a TLC memory cell, a QLC memory cell) may be physically different than an SLC cell. For example, a multiple-level memory cell 205 may use a different cell geometry or may be fabricated using different materials. In some examples, a multiple-level memory cell 205 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 205 may be illustrated as a transistor that includes a charge trapping structure (e.g., a floating gate, a replacement gate, a dielectric material) for storing an amount of charge representative of a logic value. For example, the blow-up in FIG. 2 illustrates a NAND memory cell 205-a that includes a transistor 210 (e.g., a metal-oxide-semiconductor (MOS) transistor) that may be used to store a logic value. The transistor 210 may include a control gate 215 and a charge trapping structure 220 (e.g., a floating gate, a replacement gate), where the charge trapping structure 220 may, in some examples, be between two portions of dielectric material 225. The transistor 210 also may include a first node 230 (e.g., a source or drain) and a second node 235 (e.g., a drain or source). A logic value may be stored in transistor 210 by storing (e.g., writing) a quantity of electrons (e.g., an amount of charge) on the charge trapping structure 220. An amount of charge to be stored on the charge trapping structure 220 may depend on the logic value to be stored. The charge stored on the charge trapping structure 220 may affect the threshold voltage of the transistor 210, thereby affecting the amount of current that flows through the transistor 210 when the transistor 210 is activated (e.g., when a voltage is applied to the control gate 215, when the memory cell 205-a is read). In some examples, the charge trapping structure 220 may be an example of a floating gate or a replacement gate that may be part of a 2D NAND structure. For example, a 2D NAND array may include multiple control gates 215 and charge trapping structures 220 arranged around a single channel (e.g., a horizontal channel, a vertical channel, a columnar channel, a pillar channel).

A logic value stored in the transistor 210 may be sensed (e.g., as part of a read operation) by applying a voltage to the control gate 215 (e.g., to control node 240, via a word line 265) to activate the transistor 210 and measuring (e.g., detecting, sensing) an amount of current that flows through the first node 230 or the second node 235 (e.g., via a bit line 255). For example, a sense component 270 may determine whether an SLC memory cell 205 stores a logic 0 or a logic 1 in a binary manner (e.g., based on a presence or absence of a current through the memory cell 205 when a read voltage is applied to the control gate 215, based on whether the current is above or below a threshold current). For a multiple-level memory cell 205, a sense component 270 may determine a logic value stored in the memory cell 205 based on various intermediate threshold levels of current when a read voltage is applied to the control gate 215, or by applying different read voltages to the control gate and evaluating different resulting levels of current through the transistor 210, or various combinations thereof. In one example of a multiple-level architecture, a sense component 270 may determine the logic value of a TLC memory cell 205 based on eight different levels of current, or ranges of current, that define the eight potential logic values that could be stored by the TLC memory cell 205.

An SLC memory cell 205 may be written by applying one of two voltages (e.g., a voltage above a threshold or a voltage below a threshold) to memory cell 205 to store, or not store, an electric charge on the charge trapping structure 220 and thereby cause the memory cell 205 store one of two possible logic values. For example, when a first voltage is applied to the control node 240 (e.g., via a word line 265) relative to a bulk node 245 (e.g., a body node) for the transistor 210 (e.g., when the control node 240 is at a higher voltage than the bulk), electrons may tunnel into the charge trapping structure 220. Injection of electrons into and/or removal of holes from the charge trapping structure 220 may be referred to as programming the memory cell 205 and may occur as part of a write operation. A programmed memory cell may, in some cases, be considered as storing a logic 0. When a second voltage is applied to the control node 240 (e.g., via the word line 265) relative to the bulk node 245 for the transistor 210 (e.g., when the control node 240 is at a lower voltage than the bulk node 245), electrons may leave the charge trapping structure 220. Removal of electrons from and/or injection of holes into the charge trapping structure 220 may be referred to as erasing the memory cell 205 and may occur as part of an erase operation. An erased memory cell may, in some cases, be considered as storing a logic 1. In some cases, memory cells 205 may be programmed at a page level of granularity due to memory cells 205 of a page sharing a common word line 265, and memory cells 205 may be erased at a block level of granularity due to memory cells 205 of a block sharing commonly biased bulk nodes 245.

In contrast to writing an SLC memory cell 205, writing a multiple-level (e.g., MLC, TLC, or QLC) memory cell 205 may involve applying different voltages to the memory cell 205 (e.g., to the control node 240 or bulk node 245 thereof) at a finer level of granularity to more finely control the amount of charge stored on the charge trapping structure 220, thereby enabling a larger set of logic values to be represented. Thus, multiple-level memory cells 205 may provide greater density of storage relative to SLC memory cells 205 but may, in some cases, involve narrower read or write margins or greater complexities for supporting circuitry.

A charge-trapping NAND memory cell 205 may operate similarly to a floating-gate NAND memory cell 205 but, instead of or in addition to storing a charge on a charge trapping structure 220, a charge-trapping NAND memory cell 205 may store a charge representing a logic state in a dielectric material between the control gate 215 and a channel (e.g., a channel between a first node 230 and a second node 235). Thus, a charge-trapping NAND memory cell 205 may include a charge trapping structure 220, or may implement charge trapping functionality in one or more portions of dielectric material 225, among other configurations.

In some examples, each page of memory cells 205 may be connected to a corresponding word line 265, and each column of memory cells 205 may be connected to a corresponding bit line 255 (e.g., digit line). Thus, one memory cell 205 may be located at the intersection of a word line 265 and a bit line 255. This intersection may be referred to as an address of a memory cell 205. In some cases, word lines 265 and bit lines 255 may be substantially perpendicular to one another, and may be generically referred to as access lines or select lines.

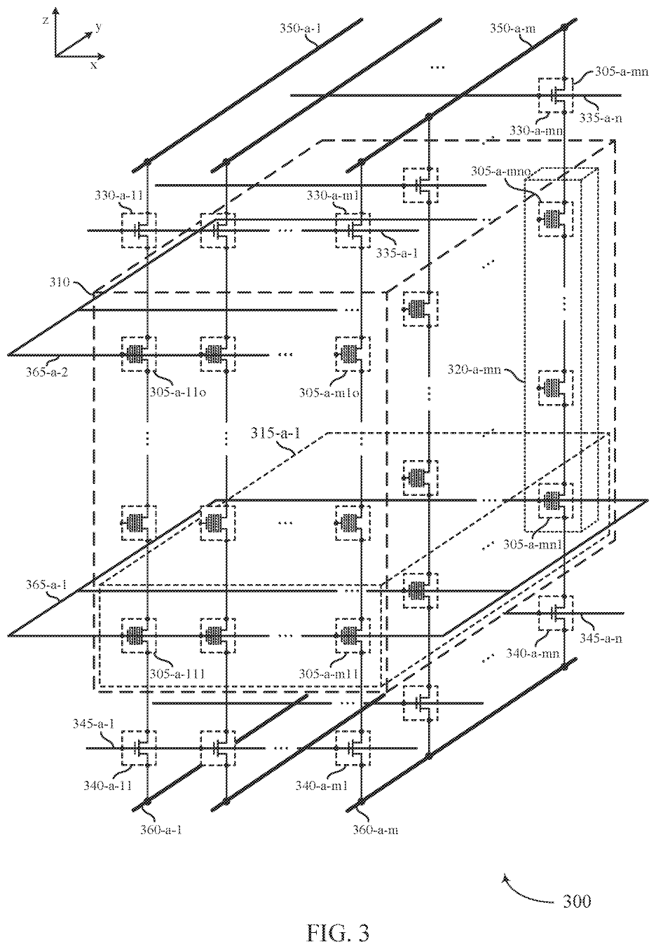

In some cases, a memory device 200 may include a three-dimensional (3D) memory array, where multiple two-dimensional (2D) memory arrays may be formed on top of one another. In some examples, such an arrangement may increase the quantity of memory cells 205 that may be fabricated on a single die or substrate as compared with 1D arrays, which, in turn, may reduce production costs, or increase the performance of the memory array, or both. In the example of FIG. 2, memory device 200 includes multiple levels (e.g., decks, layers, planes, tiers) of memory cells 205. The levels may, in some examples, be separated by an electrically insulating material. Each level may be aligned or positioned so that memory cells 205 may be aligned (e.g., exactly aligned, overlapping, or approximately aligned) with one another across each level, forming a memory cell stack 275. In some cases, memory cells aligned along a memory cell stack 275 may be referred to as a string of memory cells 205 (e.g., as described with reference to FIG. 3).

Accessing memory cells 205 may be controlled through a row decoder 260 and a column decoder 250. For example, the row decoder 260 may receive a row address from the memory controller 280 and activate an appropriate word line 265 based on the received row address. Similarly, the column decoder 250 may receive a column address from the memory controller 280 and activate an appropriate bit line 255. Thus, by activating one word line 265 and one bit line 255, one memory cell 205 may be accessed. As part of such accessing, a memory cell 205 may be read (e.g., sensed) by sense component 270. For example, the sense component 270 may be configured to determine the stored logic value of a memory cell 205 based on a signal generated by accessing the memory cell 205. The signal may include a current, a voltage, or both a current and a voltage on the bit line 255 for the memory cell 205 and may depend on the logic value stored by the memory cell 205. The sense component 270 may include various circuitry (e.g., transistors, amplifiers) configured to detect and amplify a signal (e.g., a current or voltage) on a bit line 255. The logic value of memory cell 205 as detected by the sense component 270 may be output via input/output component 290. In some cases, a sense component 270 may be a part of a column decoder 250 or a row decoder 260, or a sense component 270 may otherwise be connected to or in electronic communication with a column decoder 250 or a row decoder 260.

A memory cell 205 may be programmed or written by activating the relevant word line 265 and bit line 255 to enable a logic value (e.g., representing one or more bits of information) to be stored in the memory cell 205. A column decoder 250 or a row decoder 260 may accept data (e.g., from the input/output component 290) to be written to the memory cells 205. In the case of NAND memory, a memory cell 205 may be written by storing electrons in and/or removing holes from a charge trapping structure or an insulating layer.

A memory controller 280 may control the operation (e.g., read, write, re-write, refresh) of memory cells 205 through the various components (e.g., row decoder 260, column decoder 250, sense component 270). In some cases, one or more of a row decoder 260, a column decoder 250, and a sense component 270 may be co-located with a memory controller 280. A memory controller 280 may generate row and column address signals in order to activate a desired word line 265 and bit line 255. In some examples, a memory controller 280 may generate and control various voltages or currents used during the operation of memory device 200.

A controller (e.g., the memory controller 280) may receive a request to erase a block of a memory device. Based on the request, the controller may perform a scan operation for determining whether a threshold voltage distribution for a dummy word line associated with the block satisfies one or more criteria. Based on the scan operation, the controller may determine whether to perform one or more program and erase cycles on the block using a first voltage level for a de-biasing operation of the P/E cycle. The first voltage level may be lower than a second voltage level for one or more prior de-biasing operations of one or more prior P/E cycles performed on the block. The controller may perform an operation for managing the block of memory based on whether the P/E cycling with the debiasing operation having the voltage level is performed.

FIG. 3 illustrates an example of a memory architecture 300 that supports managing trap-up in a memory system in accordance with examples as disclosed herein. The memory architecture 300 may be an example of a portion of a memory device, such as a memory device 200. Although some elements of a set of elements (e.g., an array of elements) are included in FIG. 3, some elements may be omitted for the sake of visibility and clarity of the depicted elements. Moreover, although some elements included in FIG. 3 are labeled with reference numbers, some other corresponding elements are not labeled, though they are the same or would be understood by a person having ordinary skill in the art to be similar. Aspects of the memory architecture 300 may be described with reference to an x-direction, a y-direction, and a z-direction of the illustrated coordinate system.

The memory architecture 300 includes a three-dimensional array of memory cells 305, which may be examples of memory cells 205 described with reference to FIG. 2 (e.g., transistors 210, NAND memory cells). In some examples, the memory cells 305 may be connected in a 3D NAND configuration. For example, the memory cells 305 may be included in a block 310, which may be arranged as a 3D array of m memory cells along the x-direction, n memory cells along the y-direction, and o memory cells along the z-direction. Each memory cell 305 may be located (e.g., addressed) in accordance with an index i along the x-direction, an index j along the y-direction, and an index k along the z-direction (e.g., for locating a memory cell 305-a-ijk). A memory device 200 may include any quantity of one or more blocks 310 in accordance with examples as disclosed herein, and different blocks 310 may be adjacent along the x-direction, along they-direction, or along the z-direction, or any combination thereof.

In the example of memory architecture 300, the block 310 may be divided into a set of pages 315 (e.g., a quantity of o pages 315) along the z-direction, including a page 315-a-1 associated with memory cells 305-a-111 through 305-a-mn1. In some examples, each page 315 may be associated with a same word line 365, (e.g., a word line 265 described with reference to FIG. 2), which may be coupled with a control gate 215 of each of the memory cells 305 of the page 315. For example, page 315-a-1 may be associated with a first word line 365-a-1, and other pages 315-a-i may be associated with a different respective word line 365-a-i (not shown). In some examples, a word line 365 in accordance with the memory architecture 300 may be implemented as planar conductor (e.g., in an xy-plane) that is coupled with each of the memory cells 305 of the page 315.

In the example of memory architecture 300, the block 310 also may be divided into a set of strings 320 (e.g., a quantity of (m×n) strings 320) in an xy-plane, including a string 320-a-mn associated with memory cells 305-a-mn1 through 305-a-mno. In some examples, each string 320 may include a set of memory cells 305 connected in series (e.g., along the z-direction, in which a drain of one memory cell 305 in the string 320 may be coupled with a source of another memory cell 305 in the string 320). In some examples, memory cells 305 of a string 320 may be implemented along a common channel, such as a pillar channel (e.g., a columnar channel, a pillar of doped semiconductor) along the z-direction. Each memory cell 305 in a string 320 may be associated with a different word line 365, such that a quantity of word lines 365 in the memory architecture 300 may be equal to the quantity of memory cells 305 in a string 320. Accordingly, a string 320 may include memory cells 305 from multiple pages 315, and a page 315 may include memory cells 305 from multiple strings 320.

In some examples, memory cells 305 may be programmed (e.g., set to a logic 0 value) and read from in accordance with a granularity, such as at the granularity of the page 315, but may not be erasable (e.g., reset to a logic 1 value) in accordance with the granularity, such as the granularity of the page 315. For example, NAND memory may instead be erasable in accordance with a different (e.g., higher) level of granularity, such as at the level of granularity the block 310. In some cases, a memory cell 305 may be erased before it may be re-programmed. Different memory devices may have different read, write, or erase characteristics.

In some examples, each string 320 of a block 310 may be coupled with a respective first select transistor 330 (e.g., a string select transistor, a drain select transistor) at one end of the string 320 (e.g., along the z-direction) and a respective second select transistor 340 (e.g., a source select transistor, a ground select transistor) at the other end of the string 320. In some examples, the first select transistors 330 may be implemented using a same structure and technology as the memory cells 305. In other examples, the first select transistors 330 may be implemented as metal-oxide-semiconductor field effect transistors (MOSFETs). Similarly, the second select transistors 340 may be implemented either using a same structure and technology as the memory cells 305 or as MOSFETs. In some examples, layers of select transistors (e.g., first select transistors and second select transistors) may be implemented—e.g., to achieve long channel MOSFET effects. In some cases, the first select transistors 330 may be implemented as MOSFETs, and the second select transistors 340 may be implemented using the same technology as the memory cells 305.

In some examples, a drain of each first select transistor 330 may be coupled with a bit line 350 of a set of bit lines 350 associated with the block 310, where the bit lines 350 may be examples of bit lines 255 described with reference to FIG. 2. A gate of each first select transistor 330 may be coupled with a first select line 335 (e.g., a string select line, a drain select line). Thus, a first select transistor 330 may be used to couple a string 320 with a bit line 350 based on applying a voltage to the first select line 335, and thus to the gate of the first select transistor 330. Although illustrated as separate lines along the x-direction, in some examples, the first select lines 335 may be common to all the first select transistors 330 associated with the block 310 (e.g., a commonly biased string select node). For example, like the word lines 365 of the block 310, the first select lines 335 associated with the block 310 may, in some examples, be implemented as a planar conductor (e.g., in an xy-plane) that is coupled with each of the first select transistors 330 associated with the block 310.

In some examples, a source of each second select transistor 340 associated with the block 310 may be coupled with a source line 360 of a set of source lines 360 associated with the block 310. In some examples, the set of source lines 360 may be associated with a common source node (e.g., a ground node) corresponding to the block 310. A gate of each second select transistor 340 may be coupled with a second select line 345 (e.g., a source select line, a ground select line). Thus, a second select transistor 340 may be used to couple a string 320 with a source line 360 based on applying a voltage to the second select line 345, and thus to the gate of the second select transistor 340. Although illustrated as separate lines along the x-direction, in some examples, second select lines 345 also may be common to all the second select transistors 340 associated with the block 310 (e.g., a commonly biased ground select node). For example, like the word lines 365 of the block 310, second select lines 345 associated with the block 310 may, in some examples, be implemented as a planar conductor (e.g., in an xy-plane) that is coupled with each of the second select transistors 340 associated with the block 310.

To operate the memory architecture 300 (e.g., to perform a program operation, a read operation, or an erase operation on one or more memory cells 305 of the block 310), various voltages may be applied to one or more first select lines 335 (e.g., to the gate of the first select transistors 330), to one or more bit lines 350 (e.g., to the drain of one or more first select transistors 330), to one or more word lines 365, to one or more second select lines 345 (e.g., to the gate of the second select transistors 340), to one or more source lines 360 (e.g., to the source of the second select transistors 340), or to a bulk for the memory cells 305 (not shown) of the block 310. In some cases, each memory cell 305 of a block 310 may have a common bulk, the voltage of which may be controlled independently of bulks for other blocks 310.

In some cases, as part of a read operation for a memory cell 305, a positive voltage may be applied to the corresponding bit line 350 while the corresponding source line 360 may be grounded or otherwise biased at a voltage lower than the voltage applied to the bit line 350. In some examples, voltages may be concurrently applied to the first select line 335 and the second select line 345 that are above the threshold voltages of the first select transistor 330 and the second select transistor 340, respectively, for the memory cell 305, thereby activating the first select transistor 330 and second select transistor 340 such that a channel associated with the string 320 that includes the memory cell 305 (e.g., a pillar channel) may be electrically connected with (e.g., electrically connected between) the corresponding bit line 350 and source line 360. A channel may be an electrical path through the memory cells 305 in the string 320 (e.g., through the sources and drains of the transistors in the memory cells 305 of the string 320) that may conduct current under some operating conditions.

In some examples, multiple word lines 365 (e.g., in some cases all word lines 365) of the block 310—except a word line 365 associated with a page 315 of the memory cell 305 to be read—may concurrently be set to a voltage (e.g., VREAD) that is higher than the threshold voltage (VT) of the memory cells 305. VREAD may cause all memory cells 305 in the unselected pages 315 be activated so that each unselected memory cell 305 in the string 320 may maintain high conductivity within the channel. In some examples, the word line 365 associated with the memory cell 305 to be read may be set to a voltage, VTarget. Where the memory cells 305 are operated as SLC memory cells, VTarget may be a voltage that is between (i) VT of a memory cell 305 in an erased state and (ii) VT of a memory cell 305 in a programmed state.

When the memory cell 305 to be read exhibits an erased VT (e.g., VTarget>VT of the memory cell 305), the memory cell 305 may turn “ON” in response to the application of VTarget to the word line 365 of the selected page 315, which may allow a current to flow in the channel of the string 320, and thus from the bit line 350 to the source line 360. When the memory cell 305 to be read exhibits a programmed VT (e.g., VTarget<VT of the selected memory cell), the memory cell 305 may remain “OFF” despite the application of VTarget to the word line 365 of the selected page 315, and thus may prevent a current from flowing in the channel of the string 320, and thus from the bit line 350 to the source line 360.

A signal on the bit line 350 for the memory cell 305 (e.g., an amount of current below or above a threshold) may be sensed (e.g., by a sense component 270 as described with reference to FIG. 2), and may indicate whether the memory cell 305 became conductive or remained non-conductive in response to the application of VTarget to the word line 365 of the selected page 315. The sensed signal thus may be indicative of whether the memory cell 305 was in an erased state (e.g., storing a logic 1) or a programmed state (e.g., storing a logic 0). Though aspects of the example read operation above have been explained in the context of an SLC memory cell 305 for clarity, such techniques may be extended or altered and applied in the context of a multiple-level memory cell 305 (e.g., through the use of multiple values of VTarget corresponding to the different amounts of charge that may be stored in one multiple-level memory cell 305).

In some cases, as part of a program operation for a memory cell 305, charge may be added to a portion of the memory cell 305 such that current flow through the memory cell 305, and thus the corresponding string 320, may be inhibited when the memory cell 305 is later read. For example, charge may be injected into a charge trapping structure 220 as shown in memory cell 205-a of FIG. 2. In some cases, respective voltages may be applied to the word line 365 of the page 315 and the bulk of the memory cell 305 to be programmed such that a control gate 215 of the memory cell 305 is at a higher voltage than the bulk of the memory cell 305 (e.g., a positive voltage may be applied to the word line). Concurrently, voltages may be applied to the first select line 335 and the second select line 345 that are above the threshold voltages of the first select transistor 330 and the second select transistor 340, respectively, thereby activating the first select transistor 330 and the second select transistor 340, and the bit line 350 for the memory cell 305 to be programmed may be set to a relatively high voltage. This may cause an electric field such that electrons are pulled from the source of the memory cell 305 towards the drain and/or holes are pulled from the drain of the memory cell 305 towards the source. The electric field may also cause some of these electrons to be pulled through dielectric material 225 and thereby injected into the charge trapping structure 220 of the memory cell 305, through a process which may in some cases be referred to as tunnel injection. Additionally, or alternatively, the electric field may also cause some of these holes to be pulled out of the dielectric material 225 and thereby out of the charge trapping structure 220 of the memory cell 305

in some cases, a single program operation may program some or all memory cells 305 in a page 315, as the memory cells 305 of the page 315 may all share a common word line 365 and a common bulk. For a memory cell 305 of the page 315 for which it is not desired to write a logic 0 (e.g., not desired to program the memory cell 305), the corresponding bit line 350 may be set to a relatively low voltage (e.g., ground), which may inhibit the injection of electrons into and/or the removal of holes from a charge trapping structure 220. Though aspects of the example program operation above have been explained in the context of an SLC memory cell 305 for clarity, such techniques may be extended and applied to the context of a multiple-level memory cell 305 (e.g., through the use of multiple programming voltages applied to the word line 365, or multiple passes or pulses of a programming voltage applied to the word line 365, corresponding to the different amounts of charge that may be stored in one multiple-level memory cell 305).

In some cases, as part of an erase operation for a memory cell 305, charge may be removed from and/or holes may be injected into a portion of the memory cell 305 such that current flow through the memory cell 305, and thus the corresponding string 320, may be uninhibited (e.g., allowed, at least to a greater extent) when the memory cell 305 is later read. For example, charge may be removed from a charge trapping structure 220 as shown in memory cell 205-a of FIG. 2. In some cases, respective voltages may be applied to the word line 365 of the page 315 and the bulk of the memory cell 305 to be erased such that a control gate 215 of the memory cell 305 is at a lower voltage than the bulk of the memory cell 305 (e.g., a positive voltage may be applied to the bulk), which may cause an electric field that pulls electrons out of (and/or injection holes into) the charge trapping structure 220 and into the bulk of the memory cell 305. In some cases, a single program operation may erase all memory cells 305 in a block 310, as the memory cells 305 of the block 310 may all share a common bulk.

During the operating life of a memory device, memory cells (e.g. one or more of the memory cells 305) may wear out and lose their ability to hold particular charge states. That is, over time, the programmable VTs of the memory cells may change (e.g., drift upward, drift downward, drift closer to one another, etc.) such that the states of the memory cells may no longer be reliably programmed, detected, or both. Such memory cells may be removed from use (“retired”) and, in some examples, replaced with memory cells that have been held in reserve.

One cause for the wear out of a memory cell includes the trapping or escaping of charge (e.g., electrons) in an oxide layer between a storage element (e.g., a floating gate or replacement gate) of the memory cell and the channel of the memory cell. The trapping of charge in the oxide layer may be referred to as “trap-up.” As more charge is trapped in the oxide layer, the programmable threshold voltage(s) of the memory cell may drift higher. Alternatively, as more charge escapes from the oxide layer, the programmable threshold voltage(s) of the memory cell may drift lower. Once the programmable threshold voltage(s) of the memory cell exceed an upper threshold or fall below a lower threshold, the memory cell may lose its ability to be reliably programmed, detected, or both. A memory cell that has programmable threshold voltage(s) that exceed an upper threshold may be referred to as a high-VT memory cell.

During the operating life of a memory device, electrons that are trapped in an oxide layer of a memory cell may be freed and/or holes may be injected into the oxide layer. For example, during an erase operation, an electric field may be applied across the memory cell (e.g., during a de-biasing operation), where the application of the electric field may cause at least a subset of electrons that are trapped in the oxide layer of the memory cell to escape from the oxide layer and/or holes to be injected into the oxide layer. In some examples, the quantity of electrons that are freed from (and/or the quantity of holes injected into) the oxide layer may be based on a magnitude of the electric field applied across the oxide layer. For example, more electrons may be freed (and/or more holes injected) as the electric field applied across the oxide layer increases—e.g., as the voltage across a gate and drain of the memory device increases. Accordingly, the application of an electric field may mitigate the effects of trap-up in the memory cell. However, in some examples, the application of the electric field may be insufficient to mitigate trap-up over an extended period of time—e.g., if an electric field (e.g., a smaller electric field) applied across the oxide layer frees a smaller quantity of electrons than is trapped during other operational periods. Moreover, although applying a larger electric field to a memory cell may mitigate trap-up for the memory cell, operational considerations for a memory device may prevent a an electric field that is large enough to fully or more successfully mitigate trap-up issues from being constantly (e.g., throughout nominal operation) applied to the memory cell. In some examples, the magnitude of the electric field applied across the oxide layer is related to a voltage of the de-bias voltage applied to the transistor. For example, if the de-bias voltage is applied to the drain and a voltage applied to the gate remains constant, then the electric field applied across the oxide layer may increase as the de-bias voltage decreases.

The trap-up scenario described with reference to memory cells may similarly occur for the first select transistors 330, the second select transistors 340, or both. That is, the programmable threshold voltage of the select transistors may change (e.g., drift upward, drift downward) as more charge is trapped in, or escapes, from an oxide layer of the select transistors. Once the threshold voltage of a select transistor exceeds an upper threshold or falls below a lower threshold, the select transistor may lose its ability to be reliably operated. In some examples, the effect of trap-up (on memory cells and select transistors) may increase over the operating life of the memory device—e.g., the effect of trap-up may increase as more program and erase cycles are performed for a block. A program and erase cycle may include operations for programming a set of memory cells with data and erasing the data from the set of memory cells.

Memory cells and select transistors that have lost their ability to be reliably operated may be retired. In some examples, memory cells and select transistors are retired on a per-block basis such that once a threshold voltage of one memory cell or select transistor in a block loses the ability to be reliably programmed, detected, or both, all of the memory cells and select transistors in the block may be retired.

As described herein, the word lines 365 may be connected to respective sets of the memory cells 305. Similarly, the second select lines 345 and the source lines 360 may be connected to respective sets of select transistors. In some examples, one or more of the word lines 365 (e.g., word lines that are adjacent to the first select line 335 or the second select line 345) may be implemented as “dummy” or “placeholder” word lines (e.g., the first word line 365-a-1). Dummy word lines may be connected to memory cells that are not used by the memory system for data storage.

In some examples, the dummy word lines (e.g., the first word line 365-a-1) electrically (e.g., capacitively) couple with adjacent select lines (e.g. the second select line 345-a-1). In such cases, an electric field between the select lines and the adjacent dummy word lines may be generated when memory operations (such as program seed, inhibit, and recovery operations) are performed. For example, during an inhibit operation or recovery operation, an electric field from the first word line 365-a-1 to the second select line 345-a-1 may form and, in some examples, charge may become trapped in the oxide layer associated with the first word line 365-a-1. Also, in another example, during a program seed operation (which may also be referred to as a precharge operation), an electric field from the second select line 345-a-1 to the first word line 365-a-1 may form, and in some examples, charge may become trapped in the oxide layer of the second select line 345-a-1. As charge is trapped in the oxide layer of the second select line 345-a-1, a threshold voltage of one or more of the second select transistors 340 connected to the second select line 345-a-1 may increase. Accordingly, a voltage distribution of the threshold voltages of the second select transistors 340 connected to the second select line 345-a-1 may drift upward. Moreover, if the voltage distribution exceeds a threshold, the memory system may determine that one or more of the second select transistors 340 connected to the second select line 345-a-1 have lost the ability to be reliably operated. Dummy word lines (e.g., the second word line 365-a-2) may also electrically couple with the first select lines 335-a-1, and may similarly be subject to trap-up.

Moreover, the memory operations described above may form a positive feedback loop such that increased trap-up in the oxide layer of a dummy word line may subsequently cause increased trap-up in the oxide layer of the select lines, and vice versa, and so on. Accordingly, as more charge becomes trapped in the oxide layers of the dummy word line and the select lines, the threshold voltage distribution of the dummy word lines and select lines may drift higher at an increasing rate. In some examples, the threshold voltage distribution of a select line (e.g., the second select line 345-a-1) may increase past a voltage level, after which point the select line may be referred to as a high-VT select line. Put another way, as a dummy word line trends toward becoming a high-VT dummy word line, a corresponding select line may similarly trend toward becoming a high-VT select line. Since programming and read operations associated the high-VT select lines may be unreliable (e.g., may not occur with less than a threshold bit error rate), the memory system may be configured to retire select lines as soon as they are identified as high-VT select lines.

As described herein, as charge can be trapped in the oxide layer of a dummy word line, charge (e.g., at least a portion of the trapped charge) can also be removed (e.g., lost, released, freed) from the oxide layer. For example, trapped charge (e.g., at least a portion of the trapped charge) may be freed from the oxide layer of a dummy word line by adjusting a de-bias voltage to the dummy word line—e.g., by adjusting erase voltages across the gate and drains of the memory cells connected to the dummy word line. As described herein, an amount of charge released from the oxide layer of the dummy word line may be based on a magnitude of the de-bias voltage applied to the dummy word line—e.g., the lower the de-bias voltage applied to the dummy word line, the greater the amount of charge released from the oxide layer. Accordingly, the adjustment of the de-bias voltage may improve a trap-up condition for the dummy word line and by proxy the trap-up condition for an adjacent select line by inhibiting the positive feedback loop between these devices. In some examples, the lower the de-bias voltage applied across the dummy word line, the greater the trap-up improvement for the dummy word line and the select line will be. Moreover, although applying a lower de-bias to a memory cell may mitigate trap-up for the dummy word line (and by proxy an adjacent select line), operational considerations for a memory device may prevent a de-bias voltage that is low enough to fully or more successfully mitigate trap-up issues from being constantly (e.g., throughout nominal operation) applied to the dummy word line.

The memory system may scan (e.g., periodically, at certain cycling milestones, when an erase operation is performed for a block, etc.) the memory device for high-VT select lines—e.g., to identify whether one or more blocks associated with one or more select line are in condition to be retired. A block that is retired may be removed from the pool of operational blocks. This scan may be referred to as a high-VT scan. In some examples, once a select line is identified as having a VT that exceeds a voltage level, the scan operation immediately retires the block associated with the select line—e.g., without any attempt to recover the select line.

Retiring blocks as soon as a high-VT scanning operation identifies a respective select line as satisfying a high-VT condition may result in the unnecessary retiring of blocks, increase an overhead associated with managing retired blocks, increase memory system yield loss, and the like. Thus, configurations and techniques for avoiding the retiring blocks associated with high-VT select lines, for attempting to recover retired blocks associated with high-VT select lines, or both, may be desired.

To avoid the retiring and, in some examples, to enable recovery of retired blocks, the high-VT scanning operation may be modified to identify high-VT dummy word lines and apply (one or more times) a lowered de-bias voltage across the high-VT dummy word lines. Based on applying the lowered de-bias voltage, a determination may be made as to whether threshold voltage characteristics of the high-VT dummy word lines can be improved. If the threshold voltage characteristics of the dummy word lines can be sufficiently improved, a corresponding block may be maintained in (or, if previously retired, returned to) the pool of operational blocks. Alternatively, if the threshold voltage characteristics of the dummy word lines cannot be sufficiently improved, a corresponding block may be marked to indicate that it has limited operating life (that is, a limited quantity of remaining program and erase cycles) and, in some examples, removed from the pool of operational blocks (e.g., if the corresponding block has reached a threshold quantity of program and erase cycles).

In some examples, a request to erase a block of a memory device (e.g., the block 310) is received (e.g., at a memory controller). Based on receiving the request, the memory controller may perform a scan operation for determining whether a threshold voltage distribution for a dummy word line (the first word line 365-a-1) in the block satisfies a criteria. In some examples, the memory controller may determine that the dummy word line satisfies the criteria if the threshold voltage distribution for the dummy word line satisfies a high-VT criteria (e.g., if the threshold voltage distribution exceeds an upper limit). Based on the scan operation, the memory controller may determine whether to perform a P/E cycle for the block using a voltage level for a debiasing portion of the P/E cycle. The voltage level may be lower than a nominal voltage level for de-biasing operations, where the nominal voltage level may otherwise be used for the debiasing portion of P/E cycles during standard operation. An operation for managing the block may be performed based on whether the P/E cycles are performed. In some examples, an erase operation is subsequently completed if the reduced-voltage P/E cycles are not performed. In some examples, the block is returned to or maintained in a pool of usable blocks after the reduced-voltage P/E cycling is performed—e.g., if threshold voltage characteristics of the dummy word line improve. In some examples, the block is marked as susceptible to trap up after the reduced-voltage P/E cycling is performed—e.g., if threshold voltage characteristics of the dummy word line fail to improve or do not improve by a threshold amount.

By identifying and restoring high-VT dummy word lines, the positive feedback loop between high-VT dummy word lines and high-VT select lines may be disrupted. Thus, the occurrence of high-VT select lines may be reduced and associated blocks may be retired at a slower rate, improving yield loss characteristics for the memory system. Such techniques may be used to improve the operation of both ground select lines and source select lines.

Also, retiring fewer blocks may simplify block management operations associated with managing the blocks in a memory device. Additionally, by identifying high-VT dummy word lines that cannot be restored, blocks that are susceptible to trap-up may be identified and managed by the memory system—e.g., the memory system may increase a frequency of high-VT scanning for the identified blocks, may set a cycling limit for blocks associated with high-VT select lines that cannot be improved, etc.

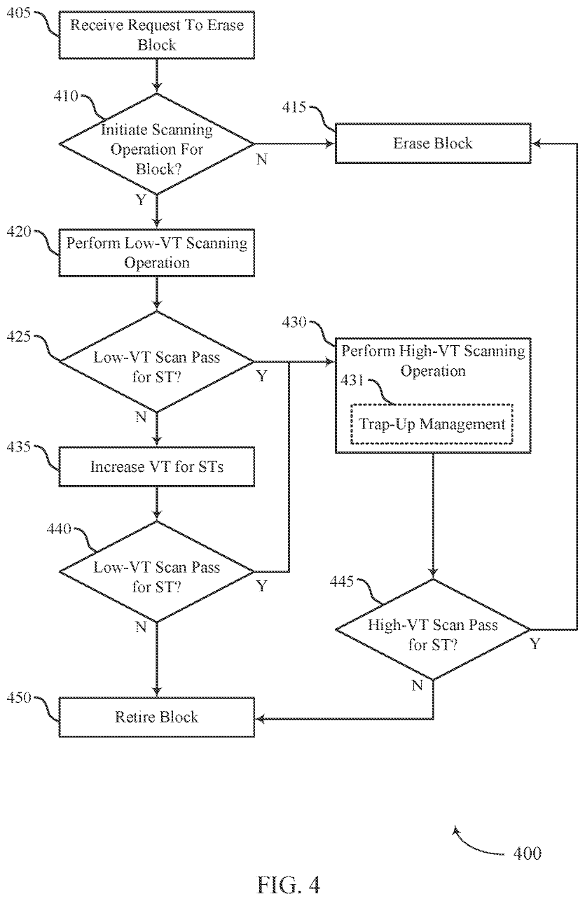

FIG. 4 illustrates an example of a set of operations for managing trap-up in a memory system in accordance with examples as disclosed herein.

The flowchart 400 may be performed by a memory system as described herein—e.g., the memory system 110 of FIG. 1. In some examples, the flowchart 400 illustrates an example set of operations performed to support managing trap-up in a memory system. For example, the flowchart 400 may include operations for performing a scanning operation for detecting low-VT and high-VT select transistors.

Aspects of the flowchart 400 may be implemented by a controller, among other components. Additionally, or alternatively, aspects of the flowchart 400 may be implemented as instructions stored in memory (e.g., firmware stored in a memory coupled with a controller). For example, the instructions, when executed by a controller, may cause the controller to perform the operations of the flowchart 400.

One or more of the operations described in the flowchart 400 may be performed earlier or later, omitted, replaced, supplemented, or combined with another operation. Also, additional operations described herein may replace, supplement or be combined with one or more of the operations described in the flowchart 400.

At 405, a request to erase a block of memory in a memory device (e.g., a memory device 130) may be received—e.g., from a host system 105 or during an internal memory operation, such as a garbage collection operation.

At 410, a determination of whether to initiate a scanning operation for the block of memory. In some examples, the scanning operation may be initiated as part of entering a diagnostic mode. In such examples, a determination of whether to enter the diagnostic mode or to remain in a nominal operation mode and erase the block may be made. The scanning operation may be configured to identify and recover low-VT select transistors in the block, high-VT select transistors in the block, or both. In some examples, the memory system determines to initiate the scanning operation based on a quantity of program and erase cycles registered for the block. For example, the scanning operation may be initiated if the quantity of program and erase cycles for the block exceeds a threshold, if a particular quantity (e.g., 500, 750, 1000, etc.) of program and erase cycles has been performed, or both. In some examples, the threshold may be dynamically determined—e.g., during operation based on the health of a block, the frequency of the scanning operation, or the like. Alternatively, the memory system may determine to not initiate the scanning operation—e.g., if the quantity of program and erase cycles for the block is less than a threshold, if the quantity of program and erase cycles is different than a particular quantity (e.g., 500, 750, 1000, etc.) of program and erase cycles, or both.

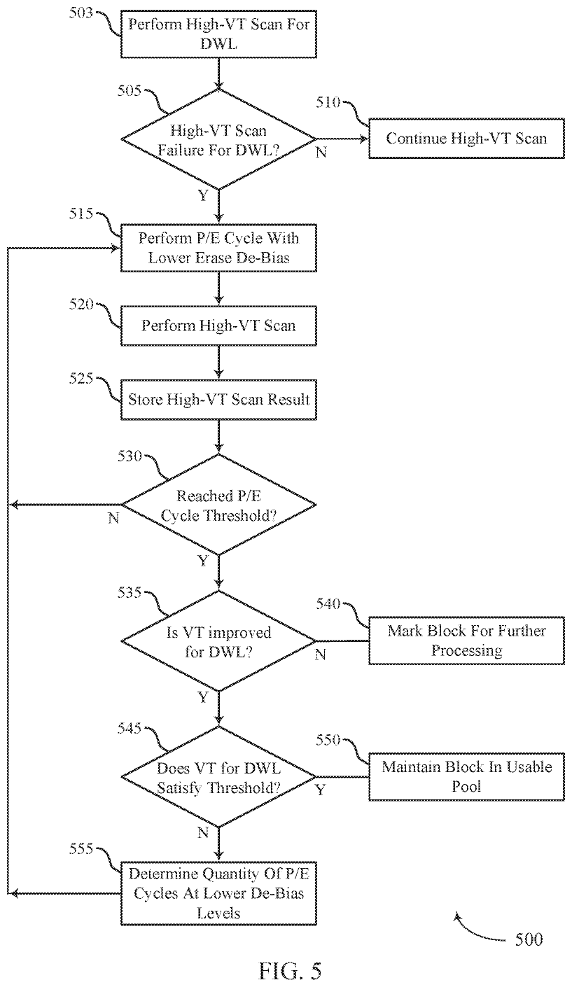

In some examples, whether the scanning operation is performed may be based on whether the block has been previously marked as susceptible to trap-up, as described in more detail herein, including with reference to FIG. 5. For example, for blocks that have been previously marked as susceptible to trap-up, the scanning operation may be performed more frequently (e.g., every 100 program and erase cycles) than for other blocks that have not been marked as susceptible to trap-up.

At 415, an operation for erasing the block (an “erase operation) may be performed based on the memory system determining that the quantity of program and erase cycles fails to satisfy a criteria for initiating a scanning operation. As part of the erase operation, a de-bias voltage may be applied to the dummy word line. The de-bias voltage may have a first voltage level.

At 420, a low-VT scanning operation for identifying threshold voltage characteristics of a select line in the block is performed as part of a procedure for determining whether the select transistors connected to the select line that have low-VTs. The low-VT scanning operation may be configured to determine whether a distribution of the threshold voltages of the select transistors (e.g., a tail of the distribution) falls outside of a range.

At 425, a determination of whether the select line qualifies as a low-VT select line is made. If a low-VT condition is identified, the memory system may proceed to perform the operations at 435 for increasing the VT of (which may also be referred to as “touching up”) the select transistors. After increasing the VT for the low VTs, at 440, the memory system may determine whether the select line after having its VT increased still qualifies as a low-VT select line. If, after having its VT increased, the select line still qualifies as a low-VT select line, the memory system may proceed to perform the operations at 450 for retiring the block—e.g., removing the block from a pool of blocks in the memory device that are available for storing data. Otherwise, if the select line no longer qualifies as a low-VT select line after having its VT increased, the memory system may proceed to perform the operations at 430 for performing a high-VT scanning operation for identifying whether the select transistors connected to the select line have high-VTs.

Alternatively, if a low-VT condition is not identified at 425, the memory system may proceed to perform the operations at 430 for performing a high-VT scanning operation for identifying whether the select transistors connected to the select line have high-VTs.

At 430, a high-VT scanning operation for identifying threshold voltage characteristics of the select line is performed as part of a procedure for identifying whether the select transistors connected to the select line have high-VTs may be performed. At least a portion of the high-VT scanning operation may be configured to determine whether a distribution of the threshold voltages of the select transistors (e.g., a tail of the distribution) falls outside of a range (e.g., the same range used for the low-VT determination). As described in more detail herein, including with reference to FIG. 5, as part of the high-VT scanning operation at 431, the memory system may perform a high-VT scanning operation for one or more dummy word lines in the block—e.g., a dummy word lines that is adjacent to the select line, electrically coupled with the select line, or both. Moreover, for high-VT dummy word lines, the memory system may attempt to recover the dummy word lines—e.g., so that the high-VT dummy word lines become nominal-VT dummy word lines. By identifying and recovering high-VT dummy word lines, the memory system may reduce trap-up within the dummy word lines and disrupt a positive feedback loop between the dummy word lines and the select line that increases trap-up in the select line.

At 445, a determination of whether the select line qualifies as a high-VT select line (e.g., even after trap-up mitigation operations are performed) may be made. If a high-VT condition is identified, the memory system may proceed to perform the operations at 450 for retiring the block. Otherwise, if a high-VT condition is not identified, the memory system may proceed to perform the operations at 450 for erasing the block.

FIG. 5 illustrates an example of a set of operations for managing trap-up in a memory system in accordance with examples as disclosed herein.

The flowchart 500 may be performed by a memory system as described herein—e.g., the memory system 110 of FIG. 1. In some examples, the flowchart 500 illustrates an example set of operations performed to support managing trap-up in a memory system. For example, the flowchart 500 may include operations for performing a scanning operation for detecting and recovering high-VT dummy word lines. The flowchart 500 may illustrate in more detail the operations for performing the trap-up management described with reference to 431 of FIG. 4.

Aspects of the flowchart 500 may be implemented by a controller, among other components. Additionally, or alternatively, aspects of the flowchart 500 may be implemented as instructions stored in memory (e.g., firmware stored in a memory coupled with a controller). For example, the instructions, when executed by a controller, may cause the controller to perform the operations of the flowchart 500.

One or more of the operations described in the flowchart 500 may be performed earlier or later, omitted, replaced, supplemented, or combined with another operation. Also, additional operations described herein may replace, supplement or be combined with one or more of the operations described in the flowchart 500.

In some examples, the operations described with reference to FIG. 5 are performed during (e.g., as part of, concurrently with) the operations for performing a high-VT scan described with reference to 430 of FIG. 4.

At 503, a high-VT scanning operation for identifying threshold voltage characteristics of the select line is performed as part of a procedure for identifying whether a dummy word line connected to the select line have high-VTs may be performed. In some examples, the scanning operation includes a check fail byte (CFBYTE) scan that monitors a slope of a threshold voltage distribution measured for the dummy word line, a read level scan that monitors a quantity of bit failures associated with the threshold voltage distribution at different read levels, or both.

At 505, a determination of whether the dummy word line qualifies as a high-VT dummy word line may be made. If a high-VT condition is not identified, the memory system may proceed to perform the operations at 510 for continuing the high-VT scan—e.g., which may include scanning additional select lines and dummy word lines in the block. Alternatively, if the high-VT condition is identified, the memory system may proceed to perform the operations at 515 as part of an attempt to restore nominal VT conditions for the dummy word lines.

At 515, a program and erase operation may be performed for the block of memory associated with the dummy word line. As part of a program and erase operation, a set of operations for programming and erasing the block may be performed. As part of the program and erase operation, different voltages may be applied to the dummy word line. For example, during the erase operation, a de-bias voltage may be applied to the dummy word line. The de-bias voltage may have a second voltage level. The second voltage level may be lower than a voltage level applied to the dummy word line during a prior erase operation. For example, the second voltage level may be lower than the first voltage level applied to the dummy word line during the erase operation described with reference to 415 of FIG. 4. In some examples, the application of the de-bias voltage to the dummy word line may cause electrons trapped in an oxide layer corresponding to the dummy word line to escape and/or holes to be injected into the oxide layer.

At 520, a subsequent high-VT scan may be performed for determining second threshold voltage characteristics of the dummy word line based on applying the lowered de-bias voltage to the dummy word line.

At 525, a result of the subsequent high-VT scan may be stored. In some examples, a result of the earlier high-VT scan performed with reference to 503 may have been previously stored—e.g., in a same area of memory as the subsequent high-VT scan.

At 530, a determination of whether a quantity of program and erase cycles performed for the dummy word line has reached a program and erase cycle threshold may be made. In some examples, (e.g., if the result of the earlier high-VT scan was stored) the program and erase cycle threshold may be equal to 1. In other examples, the program and erase cycle may be equal to more than 1 (e.g., 10). If the quantity of program and erase cycles performed for the dummy word line during the current procedure for detecting and recovering low-VT and high-VT dummy word lines is less than the program and erase cycle threshold, the memory system may proceed to repeat the operations described with reference to 515 to 525. Otherwise, the memory system may proceed to perform the operations described with reference to 535.

At 535, a determination of whether the threshold voltage characteristics for the dummy word lines have improved (as a result of the one or more program and erase operations using the lowered de-bias voltage) may be made. To determine whether the threshold voltage characteristics for the dummy word lines have improved, the memory system may compare the threshold voltage distributions that are stored at 525 (and, in some examples, stored at 503). In some examples, the memory system may determine that the threshold voltage characteristics of the dummy word line are improving if the comparison indicates that the threshold voltage distributions are shifting downward. If the memory system determines that the threshold voltage characteristics are improving, the memory system may proceed to perform the operations at 545 for determining whether the threshold voltage characteristics have improved enough.

Otherwise, at 540, the memory system may mark the block with a flag indicating that the block is susceptible to trap-up. In some examples, based on the flag being set for the block, the memory system may continue to use the block for data storage until a baseline quantity of program and erase cycles has been performed for the block—e.g., where the baseline quantity of program and erase cycles may be associated with an amount of program and erase cycles that may be performed for the blocks in the memory system without any diagnostic operations being performed for the blocks. That is, until the baseline quantity of program and erase cycles is reached, it may be assumed the block is operating nominally, even if the block is susceptible to trap-up. The memory system may retire the block once the block reaches the baseline quantity of program and erase cycles. Additionally, or alternatively, based on the flag being set for the block, the memory system may perform diagnostic operations (e.g., low-VT scanning operations, high-VT scanning operations, lowered de-bias P/E cycling operations) more frequently—e.g., relative to the schedule for blocks that are operating nominally. In some examples, performing more frequent diagnostic operations (e.g., more frequent P/E cycling operations with lowered de-bias voltages) may extend an operating life of blocks that are susceptible to trap-up.

At 545, a determination of whether the threshold voltage characteristic for the dummy word line has improved by a sufficient amount (e.g., now satisfying a threshold voltage criteria) may be made. To determine whether the threshold voltage characteristics have improved by a sufficient amount, the memory system may perform an additional high-VT scan for the dummy word line. In some examples, the memory system determines that threshold voltage characteristics for the dummy word line have increased sufficiently when the high-VT scan indicates that the threshold voltage distribution for the unused memory cells connected to the dummy word line falls within a threshold voltage range. In such cases, the memory system may perform the operations at 550 for maintaining (or returning) the block to the pool of usable blocks. Otherwise, the memory system may proceed to perform the operations at 555 for determining a quantity of program and erase cycles to apply to the dummy word line in a next round of program and erase cycles.

At 555, a determination of an additional quantity of program and erase cycles to apply to the dummy word line may be made. In some examples, the determination is based at least in part on an amount of improvement measured for the dummy word line at 545. For example, if the memory system determines that the threshold voltage characteristics for the dummy word line are nearly within range, the memory system may select a lower quantity of program and erase cycles. In some examples, the memory system also determines a different de-bias voltage level to apply during the second round of program and erase cycles. For example, if the memory system determines that the threshold voltage characteristics for the dummy word line are nearly within an acceptable range, the memory system may select a higher de-bias voltage level than the prior de-bias voltage level (though the higher de-bias voltage level may still be less than the nominal de-bias voltage level).

Subsequently, the memory system may repeat the operations described with reference to 515 to 550. Once the dummy word line has either been marked as susceptible to trap-up and/or returned to the usable pool, the memory system may continue with the high-VT scan for the remaining select line(s) and dummy word line(s) in the block.

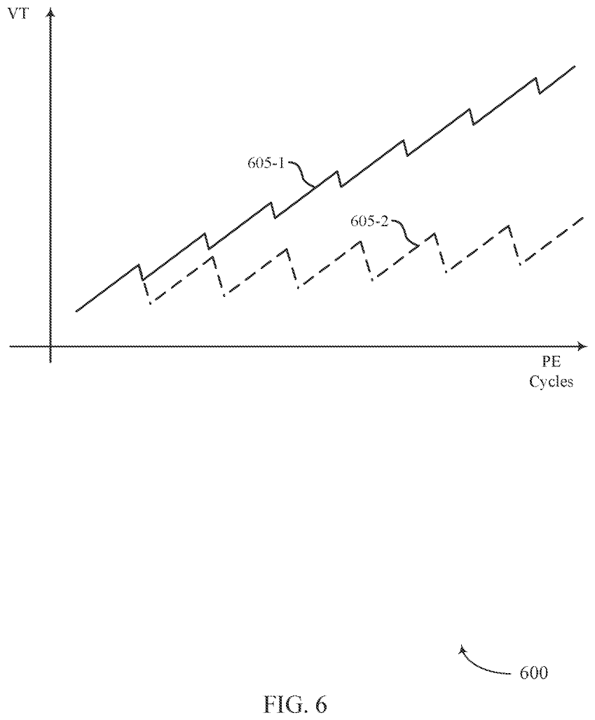

FIG. 6 illustrates an example of a diagram for managing trap-up in a memory system in accordance with examples as disclosed herein.

The diagram 600 depicts a VT for a dummy word line based on whether a program and erase cycle uses a first voltage level for a de-biasing operation or a second, lower voltage level for a de-biasing operation, where the downward portions of the lines 605 shown in the diagram 600 correspond to de-biasing operations. The first line 605-1 illustrates an increase in the VT for a dummy word line as the quantity of P/E cycles increases if a de-biasing operation uses a first voltage level. The second line 605-2 illustrates an increase in the VT for a dummy word line as the quantity of P/E cycles increases if a de-biasing operation uses a second voltage level that is lower than the first voltage level. As shown in the diagram 600, a de-biasing operation that uses a lower de-biasing voltage may slow the increase in the VT for a dummy word line relative to a de-biasing operation that uses a higher de-biasing voltage.

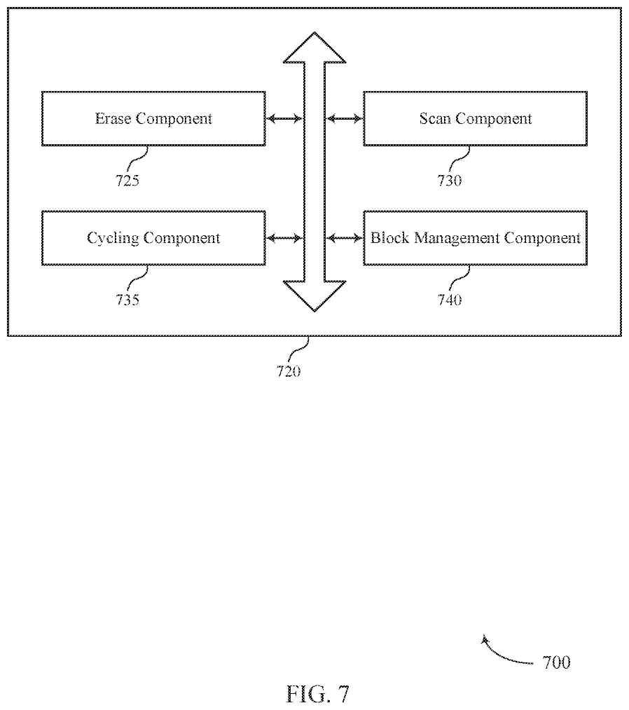

FIG. 7 illustrates a block diagram 700 of a memory system 720 that supports managing trap-up in accordance with examples as disclosed herein. The memory system 720 may be an example of aspects of a memory controller as described with reference to FIGS. 1 through 6. The memory system 720, or various components thereof, may be an example of means for performing various aspects of managing trap-up in a memory system as described herein. For example, the memory system 720 may include an erase component 725, a scan component 730, a cycling component 735, a block management component 740, or any combination thereof. Each of these components may communicate, directly or indirectly, with one another (e.g., via one or more buses).

The erase component 725 may be configured as or otherwise support a means for receiving a request to erase a block of a memory device. The scan component 730 may be configured as or otherwise support a means for performing, at a first time and based on the request, a scan operation for determining whether a threshold voltage distribution for a dummy word line associated with the block satisfies one or more criteria. The cycling component 735 may be configured as or otherwise support a means for determining, based on the scan operation, whether to perform a program and erase (P/E) cycle on the block using a first voltage level for a de-biasing operation of the P/E cycle, the first voltage level being lower than a second voltage level for a prior de-biasing operation of a prior P/E cycle performed on the block. The block management component 740 may be configured as or otherwise support a means for performing an operation to manage the block of the memory device based on whether the P/E cycle is performed.

In some examples, the scan component 730 may be configured as or otherwise support a means for determining, based on the scan operation, that the threshold voltage distribution for the dummy word line satisfies the one or more criteria, where determining whether to perform the P/E cycle includes determining to perform the P/E cycle based on the threshold voltage distribution for the dummy word line satisfying the one or more criteria. In some examples, the cycling component 735 may be configured as or otherwise support a means for performing the P/E cycle based on determining to perform the P/E cycle.

In some examples, to support performing the P/E cycle, the cycling component 735 may be configured as or otherwise support a means for applying a de-bias voltage having the first voltage level to the dummy word line.

In some examples, the scan component 730 may be configured as or otherwise support a means for performing, at a second time that occurs after the P/E cycle is performed, the scan operation for the dummy word line. In some examples, the scan component 730 may be configured as or otherwise support a means for storing, in the memory device, a second threshold voltage distribution for the dummy word line based on performing the scan operation at the second time.

In some examples, the scan component 730 may be configured as or otherwise support a means for comparing, based on the P/E cycle being performed, a first threshold voltage distribution with a second threshold voltage distribution, where the first threshold voltage distribution is measured for the dummy word line after the scan operation is performed at the first time and the second threshold voltage distribution is measured for the dummy word line after the P/E cycle is performed and the scan operation is performed at a second time. In some examples, the scan component 730 may be configured as or otherwise support a means for determining whether the second threshold voltage distribution has changed relative to the first threshold voltage distribution, where performing the operation to manage the block of the memory device is based on determining whether the second threshold voltage distribution is changed.

In some examples, the scan component 730 may be configured as or otherwise support a means for determining that a threshold quantity of P/E cycles associated with the dummy word line have been performed using the first voltage level for respective de-biasing operations, where the first threshold voltage distribution is compared with the second threshold voltage distribution based on the threshold quantity of P/E cycles having been performed.

In some examples, to support performing the operation to manage the block of the memory device, the block management component 740 may be configured as or otherwise support a means for marking the block as susceptible to trap-up based on a second threshold voltage distribution being unchanged relative to a first threshold voltage distribution, where the first threshold voltage distribution is measured for the dummy word line after the scan operation is performed at the first time and the second threshold voltage distribution is measured for the dummy word line after the P/E cycle is performed and the scan operation is performed at a second time.

In some examples, the scan component 730 may be configured as or otherwise support a means for determining whether a second threshold voltage distribution for the dummy word line satisfies the one or more criteria based on the second threshold voltage distribution being changed relative to a first threshold voltage distribution, where the first threshold voltage distribution is measured for the dummy word line after the scan operation is performed at the first time and the second threshold voltage distribution is measured for the dummy word line after the P/E cycle is performed and the scan operation is performed at a second time. In some examples, the block management component 740 may be configured as or otherwise support a means for performing the operation to manage the block of the memory device includes marking, based on determining that the second threshold voltage distribution fails to satisfy the one or more criteria, the block as a usable block.

In some examples, the scan component 730 may be configured as or otherwise support a means for determining whether a second threshold voltage distribution for the dummy word line satisfies the one or more criteria based on the second threshold voltage distribution being changed relative to a first threshold voltage distribution, where the first threshold voltage distribution is measured for the dummy word line after the scan operation is performed at the first time and the second threshold voltage distribution is measured for the dummy word line after the P/E cycle is performed and the scan operation is performed at a second time. In some examples, the cycling component 735 may be configured as or otherwise support a means for performing, based on determining that the second threshold voltage distribution continues to satisfy the one or more criteria, a second P/E cycle associated with the dummy word line using a third voltage level for a second de-biasing operation.

In some examples, the third voltage level is equivalent to the first voltage level.

In some examples, the scan component 730 may be configured as or otherwise support a means for performing, based on the request, a second scan operation for determining whether a threshold voltage distribution for a select line associated with the block satisfies the one or more criteria, where the scan operation is performed as part of the second scan operation, and where the select line and the dummy word line are electrically coupled with one another.

In some examples, the block includes the select line and the dummy word line, and the select line and the dummy word line are electrically coupled by an oxide layer that contacts the select line and the dummy word line.

In some examples, the dummy word line is connected to a plurality of memory cells in the memory device that are prevented from storing data in the memory device.

In some examples, the block management component 740 may be configured as or otherwise support a means for identifying, based on the request, a quantity of PE cycles performed for the block. In some examples, the block management component 740 may be configured as or otherwise support a means for determining, based on the quantity of P/E cycles performed for the block, to enter a diagnostic mode for analyzing threshold voltage parameters of the block, where the scan operation is performed based on the diagnostic mode being entered.

In some examples, the block management component 740 may be configured as or otherwise support a means for identifying, based on a second request to erase the block, a quantity of P/E cycles performed for the block. In some examples, the block management component 740 may be configured as or otherwise support a means for determining, based on the quantity of P/E cycles performed for the block, to remain in a nominal operating mode. In some examples, the erase component 725 may be configured as or otherwise support a means for erasing, based on remaining in the nominal operating mode, the block using the second voltage level.

In some examples, P/E cycles are configured to use the second voltage level based on the memory device operating in a nominal operating mode and to use the first voltage level based on the memory device operating in a diagnostic mode.

In some examples, the scan operation includes a check fail byte modulation or a read level modulation.

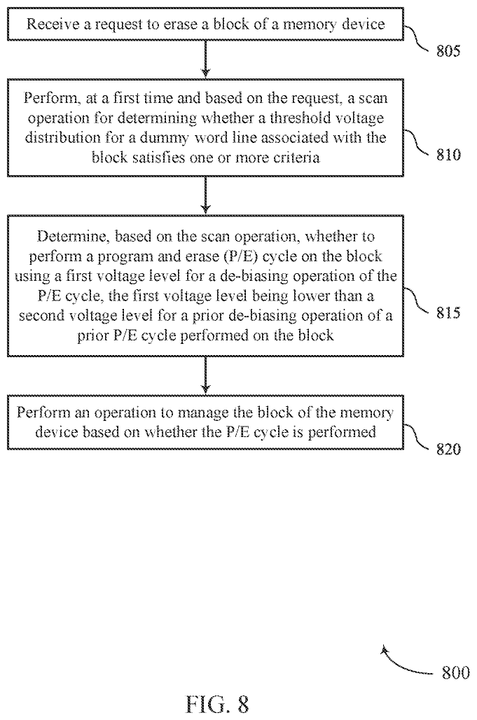

FIG. 8 illustrates a flowchart showing a method 800 that supports managing trap-up in a memory system in accordance with examples as disclosed herein. The operations of method 800 may be implemented by a memory controller or its components as described herein. For example, the operations of method 800 may be performed by a memory controller as described with reference to FIGS. 1 through 7. In some examples, a memory controller may execute a set of instructions to control the functional elements of the device to perform the described functions. Additionally, or alternatively, the memory controller may perform aspects of the described functions using special-purpose hardware.

At 805, the method may include receiving a request to erase a block of a memory device. The operations of 805 may be performed in accordance with examples as disclosed herein. In some examples, aspects of the operations of 805 may be performed by an erase component 725 as described with reference to FIG. 7.

At 810, the method may include performing, at a first time and based on the request, a scan operation for determining whether a threshold voltage distribution for a dummy word line associated with the block satisfies one or more criteria. The operations of 810 may be performed in accordance with examples as disclosed herein. In some examples, aspects of the operations of 810 may be performed by a scan component 730 as described with reference to FIG. 7.

At 815, the method may include determining, based on the scan operation, whether to perform a program and erase (P/E) cycle on the block using a first voltage level for a de-biasing operation of the P/E cycle, the first voltage level being lower than a second voltage level for a prior de-biasing operation of a prior P/E cycle performed on the block. The operations of 815 may be performed in accordance with examples as disclosed herein. In some examples, aspects of the operations of 815 may be performed by a cycling component 735 as described with reference to FIG. 7.

At 820, the method may include performing an operation to manage the block of the memory device based on whether the P/E cycle is performed. The operations of 820 may be performed in accordance with examples as disclosed herein. In some examples, aspects of the operations of 820 may be performed by a block management component 740 as described with reference to FIG. 7.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a request to erase a block of a memory device; performing, at a first time and based on the request, a scan operation for determining whether a threshold voltage distribution for a dummy word line associated with the block satisfies one or more criteria; determining, based on the scan operation, whether to perform a program and erase (P/E) cycle on the block using a first voltage level for a de-biasing operation of the P/E cycle, the first voltage level being lower than a second voltage level for a prior de-biasing operation of a prior P/E cycle performed on the block; and performing an operation to manage the block of the memory device based on whether the P/E cycle is performed.

Aspect 2: The method, apparatus, or non-transitory computer-readable medium of aspect 1, further including operations, features, circuitry, logic, means, or instructions, or any combination thereof for determining, based on the scan operation, that the threshold voltage distribution for the dummy word line satisfies the one or more criteria, where determining whether to perform the P/E cycle includes determining to perform the P/E cycle based on the threshold voltage distribution for the dummy word line satisfying the one or more criteria and performing the P/E cycle based on determining to perform the P/E cycle.

Aspect 3: The method, apparatus, or non-transitory computer-readable medium of aspect 2, where performing the P/E cycle includes operations, features, circuitry, logic, means, or instructions, or any combination thereof for applying a de-bias voltage having the first voltage level to the dummy word line.

Aspect 4: The method, apparatus, or non-transitory computer-readable medium of any of aspects 1 through 3, further including operations, features, circuitry, logic, means, or instructions, or any combination thereof for performing, at a second time that occurs after the P/E cycle is performed, the scan operation for the dummy word line and storing, in the memory device, a second threshold voltage distribution for the dummy word line based on performing the scan operation at the second time.

Aspect 5: The method, apparatus, or non-transitory computer-readable medium of any of aspects 1 through 4, further including operations, features, circuitry, logic, means, or instructions, or any combination thereof for comparing, based on the P/E cycle being performed, a first threshold voltage distribution with a second threshold voltage distribution, where the first threshold voltage distribution is measured for the dummy word line after the scan operation is performed at the first time and the second threshold voltage distribution is measured for the dummy word line after the P/E cycle is performed and the scan operation is performed at a second time and determining whether the second threshold voltage distribution has changed relative to the first threshold voltage distribution, where performing the operation to manage the block of the memory device is based on determining whether the second threshold voltage distribution is changed.

Aspect 6: The method, apparatus, or non-transitory computer-readable medium of aspect 5, further including operations, features, circuitry, logic, means, or instructions, or any combination thereof for determining that a threshold quantity of P/E cycles associated with the dummy word line have been performed using the first voltage level for respective de-biasing operations, where the first threshold voltage distribution is compared with the second threshold voltage distribution based on the threshold quantity of PE cycles having been performed.

Aspect 7: The method, apparatus, or non-transitory computer-readable medium of any of aspects 1 through 6, where performing the operation to manage the block of the memory device includes operations, features, circuitry, logic, means, or instructions, or any combination thereof for marking the block as susceptible to trap-up based on a second threshold voltage distribution being unchanged relative to a first threshold voltage distribution, where the first threshold voltage distribution is measured for the dummy word line after the scan operation is performed at the first time and the second threshold voltage distribution is measured for the dummy word line after the P/E cycle is performed and the scan operation is performed at a second time.

Aspect 8: The method, apparatus, or non-transitory computer-readable medium of any of aspects 1 through 7, further including operations, features, circuitry, logic, means, or instructions, or any combination thereof for determining whether a second threshold voltage distribution for the dummy word line satisfies the one or more criteria based on the second threshold voltage distribution being changed relative to a first threshold voltage distribution, where the first threshold voltage distribution is measured for the dummy word line after the scan operation is performed at the first time and the second threshold voltage distribution is measured for the dummy word line after the P/E cycle is performed and the scan operation is performed at a second time and performing the operation to manage the block of the memory device includes marking, based on determining that the second threshold voltage distribution fails to satisfy the one or more criteria, the block as a usable block.

Aspect 9: The method, apparatus, or non-transitory computer-readable medium of any of aspects 1 through 8, further including operations, features, circuitry, logic, means, or instructions, or any combination thereof for determining whether a second threshold voltage distribution for the dummy word line satisfies the one or more criteria based on the second threshold voltage distribution being changed relative to a first threshold voltage distribution, where the first threshold voltage distribution is measured for the dummy word line after the scan operation is performed at the first time and the second threshold voltage distribution is measured for the dummy word line after the P/E cycle is performed and the scan operation is performed at a second time and performing, based on determining that the second threshold voltage distribution continues to satisfy the one or more criteria, a second P/E cycle associated with the dummy word line using a third voltage level for a second de-biasing operation.

Aspect 10: The method, apparatus, or non-transitory computer-readable medium of aspect 9, where the third voltage level is equivalent to the first voltage level.

Aspect 11: The method, apparatus, or non-transitory computer-readable medium of any of aspects 1 through 10, further including operations, features, circuitry, logic, means, or instructions, or any combination thereof for performing, based on the request, a second scan operation for determining whether a threshold voltage distribution for a select line associated with the block satisfies the one or more criteria, where the scan operation is performed as part of the second scan operation, and where the select line and the dummy word line are electrically coupled with one another.

Aspect 12: The method, apparatus, or non-transitory computer-readable medium of aspect 11, where the block includes the select line and the dummy word line, and the select line and the dummy word line are electrically coupled by an oxide layer that contacts the select line and the dummy word line.

Aspect 13: The method, apparatus, or non-transitory computer-readable medium of any of aspects 11 through 12, where the dummy word line is connected to a plurality of memory cells in the memory device that are prevented from storing data in the memory device.

Aspect 14: The method, apparatus, or non-transitory computer-readable medium of any of aspects 1 through 13, further including operations, features, circuitry, logic, means, or instructions, or any combination thereof for identifying, based on the request, a quantity of P/E cycles performed for the block and determining, based on the quantity of P/E cycles performed for the block, to enter a diagnostic mode for analyzing threshold voltage parameters of the block, where the scan operation is performed based on the diagnostic mode being entered.

Aspect 15: The method, apparatus, or non-transitory computer-readable medium of any of aspects 1 through 14, further including operations, features, circuitry, logic, means, or instructions, or any combination thereof for identifying, based on a second request to erase the block, a quantity of P/E cycles performed for the block; determining, based on the quantity of P/E cycles performed for the block, to remain in a nominal operating mode; and erasing, based on remaining in the nominal operating mode, the block using the second voltage level.

Aspect 16: The method, apparatus, or non-transitory computer-readable medium of any of aspects 1 through 15, where P/E cycles are configured to use the second voltage level based on the memory device operating in a nominal operating mode and to use the first voltage level based on the memory device operating in a diagnostic mode.

Aspect 17: The method, apparatus, or non-transitory computer-readable medium of any of aspects 1 through 16, where the scan operation includes a check fail byte (CFBYTE) modulation or a read level modulation.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof. Some drawings may illustrate signals as a single signal, however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

As used herein, the term “substantially” means that the modified characteristic (e.g., a verb or adjective modified by the term substantially) need not be absolute but is close enough to achieve the advantages of the characteristic.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A. B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
receiving a request to erase a block of a memory device;
performing, at a first time and based on the request, a scan operation for determining whether a threshold voltage distribution for a dummy word line associated with the block satisfies one or more criteria;
determining, based on the scan operation, whether to perform a program and erase (P/E) cycle on the block using a first voltage level for a de-biasing operation of the P/E cycle, the first voltage level being lower than a second voltage level for a prior de-biasing operation of a prior P/E cycle performed on the block; and
performing an operation to manage the block of the memory device based on whether the P/E cycle is performed.

2. The method of claim 1, further comprising:
determining, based on the scan operation, that the threshold voltage distribution for the dummy word line satisfies the one or more criteria, wherein determining whether to perform the P/E cycle comprises determining to perform the P/E cycle based on the threshold voltage distribution for the dummy word line satisfying the one or more criteria; and
performing the P/E cycle based on determining to perform the P/E cycle.

3. The method of claim 2, wherein performing the P/E cycle comprises:
applying a de-bias voltage having the first voltage level to the dummy word line.

4. The method of claim 1, further comprising:
performing, at a second time that occurs after the P/E cycle is performed, the scan operation for the dummy word line; and
storing, in the memory device, a second threshold voltage distribution for the dummy word line based on performing the scan operation at the second time.

5. The method of claim 1, further comprising:
comparing, based on the P/E cycle being performed, a first threshold voltage distribution with a second threshold voltage distribution, wherein:
the first threshold voltage distribution is measured for the dummy word line after the scan operation is performed at the first time and the second threshold voltage distribution is measured for the dummy word line after the P/E cycle is performed and the scan operation is performed at a second time; and
determining whether the second threshold voltage distribution has changed relative to the first threshold voltage distribution, wherein performing the operation to manage the block of the memory device is based on determining whether the second threshold voltage distribution is changed.

6. The method of claim 5, further comprising:
determining that a threshold quantity of P/E cycles associated with the dummy word line have been performed using the first voltage level for respective de-biasing operations, wherein the first threshold voltage distribution is compared with the second threshold voltage distribution based on the threshold quantity of P/E cycles having been performed.

7. The method of claim 1, wherein performing the operation to manage the block of the memory device comprises:
marking the block as susceptible to trap-up based on a second threshold voltage distribution being unchanged relative to a first threshold voltage distribution, wherein the first threshold voltage distribution is measured for the dummy word line after the scan operation is performed at the first time and the second threshold voltage distribution is measured for the dummy word line after the P/E cycle is performed and the scan operation is performed at a second time.

8. The method of claim 1, further comprising:
determining whether a second threshold voltage distribution for the dummy word line satisfies the one or more criteria based on the second threshold voltage distribution being changed relative to a first threshold voltage distribution, wherein:
the first threshold voltage distribution is measured for the dummy word line after the scan operation is performed at the first time and the second threshold voltage distribution is measured for the dummy word line after the P/E cycle is performed and the scan operation is performed at a second time; and
performing the operation to manage the block of the memory device comprises marking, based on determining that the second threshold voltage distribution fails to satisfy the one or more criteria, the block as a usable block.

9. The method of claim 1, further comprising:
determining whether a second threshold voltage distribution for the dummy word line satisfies the one or more criteria based on the second threshold voltage distribution being changed relative to a first threshold voltage distribution, wherein:
the first threshold voltage distribution is measured for the dummy word line after the scan operation is performed at the first time and the second threshold voltage distribution is measured for the dummy word line after the P/E cycle is performed and the scan operation is performed at a second time; and
performing, based on determining that the second threshold voltage distribution continues to satisfy the one or more criteria, a second P/E cycle associated with the dummy word line using a third voltage level for a second de-biasing operation.

10. The method of claim 9, wherein the third voltage level is equivalent to the first voltage level.

11. The method of claim 1, further comprising:
performing, based on the request, a second scan operation for determining whether a threshold voltage distribution for a select line associated with the block satisfies the one or more criteria, wherein the scan operation is performed as part of the second scan operation, and wherein the select line and the dummy word line are electrically coupled with one another.

12. The method of claim 11, wherein:
the block comprises the select line and the dummy word line, and
the select line and the dummy word line are electrically coupled by an oxide layer that contacts the select line and the dummy word line.

13. The method of claim 11, wherein:
the dummy word line is connected to a plurality of memory cells in the memory device that are prevented from storing data in the memory device.

14. The method of claim 1, further comprising:
identifying, based on the request, a quantity of P/E cycles performed for the block; and
determining, based on the quantity of P/E cycles performed for the block, to enter a diagnostic mode for analyzing threshold voltage parameters of the block, wherein the scan operation is performed based on the diagnostic mode being entered.

15. The method of claim 1, further comprising:
identifying, based on a second request to erase the block, a quantity of P/E cycles performed for the block;
determining, based on the quantity of P/E cycles performed for the block, to remain in a nominal operating mode; and
erasing, based on remaining in the nominal operating mode, the block using the second voltage level.

16. The method of claim 1, wherein P/E cycles are configured to use the second voltage level based on the memory device operating in a nominal operating mode and to use the first voltage level based on the memory device operating in a diagnostic mode.

17. The method of claim 1, wherein the scan operation comprises a check fail byte (CFBYTE) modulation or a read level modulation.

18. An apparatus, comprising:
a memory device; and
a controller coupled with the memory device and configured to cause the apparatus to:
receive a request to erase a block of the memory device;
perform, at a first time and based on the request, a scan operation for determining whether a threshold voltage distribution for a dummy word line associated with the block satisfies one or more criteria;
determine based on the scan operation, whether to perform a program and erase (P/E) cycle on the block using a first voltage level for a de-biasing operation of the P/E cycle, the first voltage level being lower than a second voltage level for a prior de-biasing operation of a prior P/E cycle performed on the block; and
perform an operation to manage the block of the memory device based on whether the P/E cycle is performed.

19. The apparatus of claim 18, wherein the controller is further configured to cause the apparatus to:
determine, based on the scan operation, that the threshold voltage distribution for the dummy word line satisfies the one or more criteria, wherein, to determine whether to perform the P/E cycle, the controller is further configured to cause the apparatus to determine to perform the P/E cycle based on the threshold voltage distribution for the dummy word line satisfying the one or more criteria; and
perform the P/E cycle based on determining to perform the P/E cycle.

20. A non-transitory, computer-readable medium that stores code comprising instructions that are executable by a processor of an electronic device to cause the electronic device to:
receive a request to erase a block of a memory device;
perform, at a first time and based on the request, a scan operation for determining whether a threshold voltage distribution for a dummy word line associated with the block satisfies one or more criteria;
determine based on the scan operation, whether to perform a program and erase (P/E) cycle on the block using a first voltage level for a de-biasing operation of the P/E cycle, the first voltage level being lower than a second voltage level for a prior de-biasing operation of a prior P/E cycle performed on the block; and
perform an operation to manage the block of the memory device based on whether the P/E cycle is performed.
